(19) United States
(12) Patent Application Publication
(10) Pub. No.: US 2026/0314246 A1
(43) Pub. Date: Oct. 8, 2026

(54) MOTHER SUBSTRATE AND METHOD OF MANUFACTURING DISPLAY PANEL

(71) Applicant: Samsung Display Co., LTD., Yongin-si (KR)

(72) Inventors: SUNYOUNG KIM, Yongin-si (KR); MAENGHA LEE, Yongin-si (KR); JAE-MAN LEE, Yongin-si (KR)

(21) Appl. No.: 19/385,572

(22) Filed: Nov. 11, 2025

(30) Foreign Application Priority Data
Apr. 2, 2025 (KR) 10-2025-0042627

(51) Int. Cl. H10K 59/88; H10K 59/12; H10K 59/121; H10K 59/80; H10K 71/80; H10K 102/00

(52) U.S. Cl. CPC H10K 59/88; H10K 59/1201; H10K 59/1213; H10K 59/873; H10K 71/80; H10K 2102/351

(57) ABSTRACT

A mother substrate includes a base substrate, a plurality of cells, a plurality of protective layers, and a dummy pattern. A plurality of active regions and a dummy region surrounding the plurality of active regions are defined on the base substrate. The plurality of cells are positioned on the base substrate, overlap the active regions, respectively, and include a plurality of light-emitting diodes. The plurality of protective layers are disposed on the plurality of cells, respectively, and overlap the plurality of active regions, respectively. The dummy pattern overlaps the dummy region and is formed of the same material as the protective layers.

This application claims priority to Korean Patent Application No. 10-2025-0042627, filed on Apr. 2, 2025, and all the benefits accruing therefrom under 35 U.S.C. § 119, the content of which in its entirety is herein incorporated by reference.

### BACKGROUND

### 1. Field

The present disclosure relates to a mother substrate and a method of manufacturing a display panel, which are configured to prevent the mother substrate from warping or twisting during the manufacturing process of the display panel. More specifically, the present disclosure pertains to a mother substrate having an added pattern in a dummy region and a method of manufacturing a display panel using the same.

### 2. Description of the Related Art

A display device may include a display panel and a functional layer disposed beneath the display panel. In the process of manufacturing the display panel, a plurality of cells are formed on a mother substrate, and a cell-cutting process is carried out along cell-cut grooves formed between the plurality of cells. Additionally, an inkjet printing device may be employed to form patterns and layers during the manufacturing of the display device.

For instance, the functional layer may be formed by applying a resin underneath the display panel. The functional layer may be formed using an air floating method, in which the mother substrate is levitated by a predetermined distance on a stage.

However, a problem may arise in which the mother substrate warps or twists due to a thickness variation between the plurality of cells and the dummy region where the plurality of cells are not present.

### SUMMARY

The present disclosure aims to provide a mother substrate and a method of manufacturing a display panel that are configured to prevent warping or twisting of the mother substrate during the display panel manufacturing process.

Specifically, the present disclosure aims to provide a mother substrate having an added pattern in a dummy region and a method of manufacturing a display panel using such a mother substrate.

According to one embodiment of the present disclosure, a mother substrate includes a base substrate, a plurality of cells, a plurality of protective layers, and a dummy pattern. A plurality of active regions and a dummy region surrounding the plurality of active regions are defined on the base substrate. The plurality of cells are disposed on the base substrate, overlap the active regions, respectively, and include a plurality of light-emitting diodes. The plurality of protective layers are disposed on the plurality of cells, respectively, and overlap the active regions, respectively. The dummy pattern overlaps the dummy region and is formed of the same material as the protective layers.

In an embodiment, each of the plurality of cells may include a circuit layer, a light-emitting layer, and an encapsulation layer. The circuit layer may include a plurality of transistors and may be disposed on the base substrate. The light-emitting layer may be disposed on the circuit layer and may include at least some of the plurality of light-emitting diodes. The encapsulation layer may be disposed on the light-emitting layer.

In an embodiment, each of the protective layers may include at least one of an acrylic resin, an epoxy resin, and a silicon resin.

In an embodiment, a plurality of cell-cut grooves may be defined in the dummy region. The cell-cut grooves may include a plurality of first cell-cut grooves and a plurality of second cell-cut grooves. Each of the first cell-cut grooves may extend along a first direction, and each of the second cell-cut grooves may extend along a second direction intersecting the first direction. A portion of the dummy pattern may be disposed between two adjacent second cell-cut grooves.

In an embodiment, another portion of the dummy pattern may be disposed between two adjacent first cell-cut grooves.

In an embodiment, another portion of the dummy pattern may be disposed between an outermost first cell-cut groove of the plurality of first cell-cut grooves and one side of the base substrate adjacent to the outermost first cell-cut groove.

In an embodiment, another portion of the dummy pattern may be disposed between an outermost second cell-cut groove and another side of the base substrate adjacent to the outermost second cell-cut groove.

In an embodiment, the mother substrate may further include a functional layer disposed under the base substrate.

In an embodiment, the functional layer may include at least one of carbon black, graphite, and carbon nanotubes.

In an embodiment, the thickness of each of the plurality of protective layers may be greater than or equal to 100 micrometers and smaller than or equal to 150 micrometers.

In an embodiment, the thickness of each of the protective layers may be smaller than the thickness of the dummy pattern.

According to one embodiment of the present disclosure, a method of manufacturing a display panel includes providing a base substrate, forming a circuit layer, forming a light-emitting layer, forming an encapsulation layer, and forming a cover layer. In the step of providing a base substrate, a base substrate is provided in which a plurality of active regions and a dummy region surrounding the plurality of active regions are defined. In the step of forming a circuit layer, a circuit layer including a plurality of transistors overlapping the plurality of active regions is formed on the base substrate. In the step of forming the light-emitting layer, the light-emitting layer including a plurality of light-emitting diodes is formed on the circuit layer. In the step of forming an encapsulation layer, the encapsulation layer is formed on the light-emitting layer. In the step of forming a cover layer, a material including an organic material is coated to form a plurality of protective layers overlapping the plurality of active regions and a dummy pattern overlapping the dummy region.

In an embodiment, the method may further include forming a cell-cut groove. In the step of forming the cell-cut groove, a plurality of cell-cut grooves may be defined in the dummy region. The plurality of cell-cut grooves may include a plurality of first cell-cut grooves and a plurality of second cell-cut grooves. Each of the plurality of first cell-cut grooves may extend along a first direction, and each of the plurality of second cell-cut grooves may extend along a second direction intersecting the first direction.

In an embodiment, a portion of the dummy pattern may be disposed between two adjacent second cell-cut grooves.

In an embodiment, another portion of the dummy pattern may be disposed between two adjacent first cell-cut grooves.

In an embodiment, another portion of the dummy pattern may be disposed between an outermost first cell-cut groove of the plurality of first cell-cut grooves and one side of the base substrate adjacent to the outermost first cell-cut groove.

In an embodiment, the step of forming the cover layer may be performed using an inkjet printing device that includes a stage and a nozzle unit disposed on the stage. The step of forming the cover layer may include positioning the base substrate, ejecting ink, and curing the ink. In the step of positioning the base substrate, the base substrate may be positioned on the stage such that the encapsulation layer faces the nozzle unit. In the step of ejecting ink, the organic material may be ejected through the nozzle unit onto the plurality of active regions and the dummy region. In the step of curing the ink, the ejected organic material may be cured.

In an embodiment, the organic material may include at least one of an acrylic resin, an epoxy resin, and a silicon resin.

In an embodiment, after the step of forming the cover layer, the method may further include turning the base substrate over, floating the base substrate, and forming a functional layer. In the step of turning the base substrate over, the base substrate may be positioned such that a rear surface of the base substrate faces the nozzle unit. In the step of floating the base substrate, air may be supplied toward the base substrate from the stage to levitate the base substrate so that the base substrate is spaced apart from the stage. In the step of forming a functional layer, a material including black color may be coated to the rear surface of the base substrate to form the functional layer.

In an embodiment, after the step of ejecting ink, the thickness of each of the plurality of protective layers may be smaller than the thickness of the dummy pattern.

In one embodiment, after the step of forming a functional layer, the functional layer may include at least one of carbon black, graphite, and carbon nanotubes.

The present disclosure can provide a mother substrate and a method of manufacturing a display panel that are configured to prevent warping or twisting of the mother substrate during the display panel manufacturing process.

Specifically, the present disclosure can provide a mother substrate having an added pattern in a dummy region and a method of manufacturing a display panel using such a mother substrate.

### BRIEF DESCRIPTION OF THE DRAWINGS

These and/or other features will become apparent and more readily appreciated from the following description of the embodiments, taken in conjunction with the accompanying drawings in which:

FIG. 1 is a perspective view illustrating an example of an electronic device according to an embodiment of the present disclosure;

FIG. 2 is a cross-sectional view illustrating an example of an electronic device according to an embodiment of the present disclosure;

FIG. 3 is a plan view illustrating an example of a display module according to an embodiment of the present disclosure;

FIG. 4 is a cross-sectional view illustrating an example of a display panel according to an embodiment of the present disclosure;

FIG. 5A is a plan view of a mother substrate according to an embodiment of the present disclosure;

FIG. 5B is a cross-sectional view taken along line I-I′ of FIG. 5A;

FIG. 6 illustrates the extent to which a base substrate is floated from a stage;

FIG. 7A is a plan view of a mother substrate according to another embodiment of the present disclosure;

FIG. 7B is a plan view of a mother substrate according to yet another embodiment of the present disclosure;

FIG. 7C is a plan view of a mother substrate according to still another embodiment of the present disclosure;

FIG. 7D is a cross-sectional view illustrating an example of a mother substrate according to another embodiment of the present disclosure;

FIG. 8 is a flow diagram illustrating a method of manufacturing a display panel according to an embodiment of the present disclosure; and

FIGS. 9A to 9K are sequential views illustrating a method of manufacturing a display panel according to an embodiment of the present disclosure.

### DETAILED DESCRIPTION

References will now be made in detail to certain embodiments, of which examples are illustrated in the accompanying drawings, where like reference numerals refer to like elements throughout. The embodiments may have a variety of forms and permutations, but the present disclosure shall by no means be construed as being limited to the described embodiments. Rather, the present disclosure shall be construed to encompass all forms, permutations, equivalents and substitutes covered by the technical ideas and scope of the present disclosure. Accordingly, the embodiments are merely described below, by referring to the figures, to explain features of the present disclosure.

In the accompanying drawings, the thicknesses, ratios, and dimensions of the illustrated elements may not be to exact scale and may have been exaggerated for the benefit of effective explanation of the technical features associated with these elements. As such, the present disclosure shall not be restricted to the thicknesses, ratios, dimensions, etc. illustrated in the drawings. The term “and/or” encompasses all possible combinations of the associated elements as defined.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items.

An expression such as “comprise” or “include” is intended to specify the presence of a characteristic, a number, a step, an operation, an element, a part, or combinations thereof described in the specification, and shall not be construed to preclude any possibility of presence or addition of one or more other characteristics, numbers, steps, operations, elements, parts, or combinations thereof.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

FIG. 1 is a perspective view illustrating an electronic device ED according to an embodiment of the present disclosure. In FIG. 1, the electronic device ED is exemplified as a display device that reproduces images. The display device may be, for example, but not limited to, a liquid crystal display (LCD), a field emission display (FED), an electro phoretic display (EPD), an electro-wetting display (EWD), an organic light emitting display (OLED), or a quantum dot display (QD).

The electronic device ED may be a device activated by electrical signals. For example, the electronic device ED may be a large electronic device, such as a screen and an outdoor billboard, as well as a medium- or small-sized device, such as a desktop computer, a notebook computer, a navigation system, a gaming console, a smartphone, and a tablet PC. The listed examples of electronic devices ED are merely illustrative, and the concepts of the present disclosure may be employed in other types of electronic devices without departing from the scope of the disclosure.

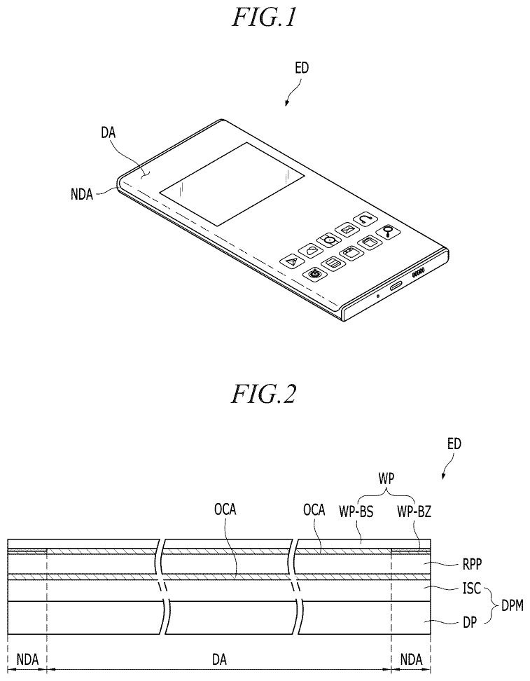

FIG. 2 is a cross-sectional view illustrating an electronic device ED according to an embodiment of the present disclosure. Illustration in FIG. 2 is simplified to describe the stacking relationship of functional panels or functional members constituting the electronic device ED.

As illustrated in FIG. 2, the electronic device ED may include a display panel DP, an input sensing circuit ISC, an anti-reflection member RPP, and a window member WP. The input sensing circuit ISC may be disposed directly on the display panel DP. In this specification, being “disposed directly” means that no other adhesive layer or adhesive member is interposed between the two components.

In this specification, the display panel DP together with the input sensing circuit ISC disposed thereon may collectively be referred to as a display module DPM. An optically clear adhesive member OCA may be disposed between the display module DPM and the anti-reflection member RPP and also between the anti-reflection member RPP and the window member WP.

The display panel DP is configured to generate images, and the input sensing circuit ISC is configured to obtain coordinate information of an external input (e.g., microcurrent or applied pressure). Although not explicitly illustrated, the display module DPM according to an embodiment of the present disclosure may further include a protective member disposed on the bottom surface of the display panel DP. The protective member and the display panel DP may be bonded by an adhesive member.

The display panel DP according to an embodiment of the present disclosure may be a light-emitting-type display panel. For example, the display panel DP may be an organic light emitting display panel, a quantum dot light emitting display panel, or a micro light emitting display panel. The light-emitting layer of the organic light emitting display panel may include an organic light-emitting material. The inorganic light emitting display panel may be based on inorganic materials and may include quantum dot light emitting panel and micro light emitting display panels. Hereinafter, the display panel DP is described as an organic light emitting display panel.

The anti-reflection member RPP is configured to reduce the reflectance of external light incident from above the window member WP. According to an embodiment of the present disclosure, the anti-reflection member RPP may include a retarder and a polarizer. In an embodiment, the anti-reflection member RPP may include color filters.

The window member WP according to an embodiment of the present disclosure may include a base film WP-BS and a light-shielding pattern WP-BZ. The base film WP-BS may include glass or synthetic resin. The base film WP-BS is not limited to a single layer and may include two or more films bonded together by an adhesive member.

The light-shielding pattern WP-BZ partially overlaps the base film WP-BS. The light-shielding pattern WP-BZ may be disposed on a rear surface of the base film WP-BS to define a bezel region of the electronic device ED, that is, the non-display area NDA.

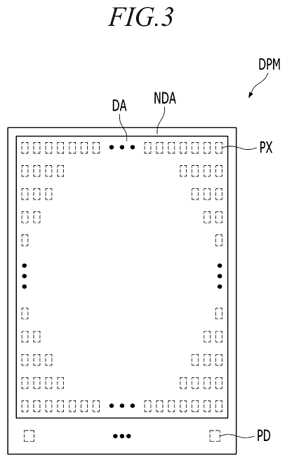

FIG. 3 is a plan view illustrating the display module DPM according to an embodiment of the present disclosure. The display module DPM may include a display panel DP and signal pads PD.

The display panel DP may have a display area DA and a non-display area NDA defined therein. The non-display area NDA may surround the display area DA. The display area DA may be the region where images are displayed. A plurality of pixels PX may be disposed to overlap the display area DA. The plurality of pixels PX may be arranged on the display panel DP in a specific layout. For example, the plurality of pixels PX may be arranged in the shape of a matrix. Additionally, each of the plurality of pixels PX may be configured to display a different color on the display panel DP.

Although not explicitly illustrated in this specification, the display module DPM may further include a data driving circuit (not shown) and a flexible printed circuit board (not shown).

The data driving circuit (not shown) may be installed on the display panel DP in the form of an integrated circuit (IC) chip. The data driving circuit may serve as a component for transferring data signals to the pixels PX.

The signal pads PD may be installed on the flexible printed circuit board (not shown). That is, the signal pads PD may be disposed in the non-display area NDA of the display panel DP. The signal pads PD may be electrically connected to the data driving circuit (not shown) and transmit signals for operating the data driving circuit (not shown).

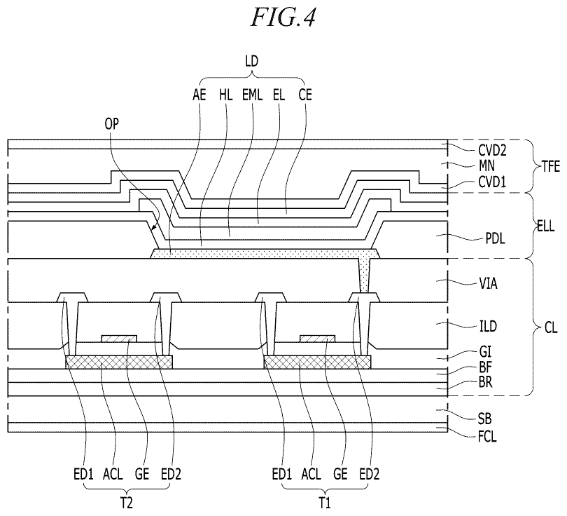

FIG. 4 is a cross-sectional view illustrating the display panel DP according to an embodiment of the present disclosure. In FIG. 4, a first transistor T1 and a second transistor T2 are illustrated as examples; however, the structures of the first transistor T1 and the second transistor T2 are not limited thereto. While FIG. 4 depicts as if a second electrode ED2 of the first transistor T1 is in direct contact with an anode electrode AE of a pixel PX, such illustration is due to being a cross-sectional view. In practice, the first transistor T1 may be connected to the anode electrode AE of the pixel PX via an intermediate transistor (not shown). However, the present disclosure is not limited thereto, and in other embodiments, the second electrode ED2 of the first transistor T1 may be in direct contact with the anode electrode AE of the pixel PX.

The display panel DP may include a substrate SB, a circuit layer CL, a light-emitting layer ELL, an encapsulation layer TFE, and a functional layer FCL.

The substrate SB may serve as a base for the circuit layer CL. That is, other components of the circuit layer CL may be stacked on the substrate SB.

The substrate SB may be made of an insulating material such as glass, quartz, or polymer resin. For example, the substrate SB may be made of polyethersulfone (PES), polyacrylate (PA), polyarylate (PAR), polyetherimide (PEI), polyethylene naphthalate (PEN), polyethylene terephthalate (PET), polyphenylene sulfide (PPS), polyallylate, polycarbonate (PC), cellulosetriacetate (CAT), cellulose acetate propionate (CAP), or combinations thereof.

The substrate SB may include a metallic material. The substrate SB may be a rigid substrate or a flexible substrate capable of bending, folding, or rolling. An example of a material suitable for the flexible substrate includes, but is not limited to, polyimide (PI). In this specification, the substrate SB may be understood as a layer resulting from cutting the base substrate BSB during the cell cutting process in the display panel manufacturing process.

The circuit layer CL may include a barrier layer BR, a buffer layer BF, a gate insulating layer GI, an interlayer insulating layer ILD, a circuit insulating layer VIA, and transistors T1, T2.

The light-emitting layer ELL may be disposed on the circuit layer CL. The light-emitting layer ELL may include a light-emitting diode LD and a pixel defining layer PDL.

The encapsulation layer TFE is configured to seal the light-emitting layer ELL to protect it from external oxygen or moisture. The encapsulation layer TFE may include a first inorganic layer CVD1, an organic layer MN, and a second inorganic layer CVD2. Although FIG. 4 illustrates an example in which the encapsulation layer TFE includes two inorganic layers and one organic layer, the present disclosure is not limited thereto. For example, the encapsulation layer TFE may include three inorganic layers and two organic layers, in which case the inorganic and organic layers may be alternately stacked.

The barrier layer BR is configured to prevent impurities present in the underlying layers during the manufacturing process from being introduced into the pixel PX. Particularly, the barrier layer BR prevents impurities from diffusing into the active regions ACL of the transistors T1, T2 constituting the pixel PX.

Active regions ACL constituting respective transistors T1, T2 are disposed on the buffer layer BF. Each of the active regions ACL may include poly silicon or amorphous silicon. Additionally, the active regions ACL may include a metal oxide semiconductor.

The active regions ACL may include a channel region, through which electrons or holes move, and a first ion-doped region and a second ion-doped region disposed with the channel region disposed therebetween.

A gate insulating layer GI that covers the active regions ACL may be disposed on the buffer layer BF. The gate insulating layer GI may include an organic film and/or an inorganic film. The gate insulating layer GI may include a plurality of inorganic thin films, which may include a silicon nitride layer and a silicon oxide layer.

Control electrodes GE constituting the respective transistors T1, T2 are disposed on the gate insulating layer GI. At least a portion of scan lines (not shown) and emission control lines (not shown) may also be disposed on the gate insulating layer GI.

An interlayer insulating layer ILD covering the control electrodes GE is disposed on the gate insulating layer GI. The interlayer insulating layer ILD may include an organic film and/or an inorganic film. The interlayer insulating layer ILD may include a plurality of inorganic or organic thin films. The plurality of inorganic thin films may include a silicon nitride layer and a silicon oxide layer.

At least a portion of data lines (not shown) and power lines (not shown) may be disposed on the interlayer insulating layer ILD. First electrodes ED1 and second electrodes ED2 of the respective transistors T1, T2 may be disposed on the interlayer insulating layer ILD.

The first electrodes ED1 and the second electrodes ED2 may be connected to the corresponding active regions ACL through contact holes penetrating the gate insulating layer GI and the interlayer insulating layer ILD.

A circuit insulating layer VIA covering the first electrodes ED1 and the second electrodes ED2 may be disposed on the interlayer insulating layer ILD. The circuit insulating layer VIA may include an organic film and/or an inorganic film and may provide a flat surface. The circuit insulating layer VIA may be disposed between the anode electrode AE and the transistors T1, T2. The pixel defining layer PDL and the light-emitting diode LD may be disposed on the circuit insulating layer VIA.

The light-emitting diode LD may include an anode electrode AE, a hole control layer HL, a light-emitting layer EML, an electron control layer EL, and a cathode electrode CE. The anode electrode AE may be connected to the second electrode ED2 through a contact hole penetrating the circuit insulating layer VIA. An opening OP defined in the pixel defining layer PDL may expose the anode electrode AE.

A functional layer FCL may be bonded to a rear surface of the display panel DP. Here, the functional layer FCL and the substrate SB of the display panel DP may be in direct contact with each other without an adhesive member interposed therebetween.

The functional layer FCL disposed on the rear surface of the display panel DP may be a plurality of functional layers configured to perform various functions. Moreover, the plurality of functional layers FCL may be fabricated separately and then attached to the underside of the display panel DP using an adhesive. However, foreign substances may become introduced between the display panel DP and the plurality of functional layers FCL during the manufacturing process, which can degrade the display efficiency of the display device. Consequently, the efficiency of the manufacturing process may be reduced. Therefore, in recent approaches, a technique has been employed in which a high-viscosity resin containing a filler is applied to the underside of the display panel DP to form the plurality of functional layers FCL.

The functional layer FCL according to an embodiment of the present disclosure may serve as a light-shielding layer. The functional layer FCL may be bonded to the rear surface of the display panel DP to protect the rear surface from external impacts and enhance visibility. Specifically, in the present disclosure, the display panel DP may include the substrate SB and the pixels PX disposed on the substrate SB. External light incident on the front surface of the display panel DP or light generated by the pixels PX during the operation of the display panel DP may be emitted toward the rear surface of the display panel DP. As a result, components disposed on the rear surface of the display panel DP may become visible from the front surface due to the external light. The functional layer FCL may be configured to block visibility through the rear surface of the display panel DP, thereby preventing the components disposed on the rear surface from being seen from the front of the display module. However, this is merely an example, and the present disclosure is not limited thereto.

The functional layer FCL according to an embodiment of the present disclosure may include at least one of carbon black, graphite, and carbon nanotubes. In another example, the functional layer FCL may include a black-colored light-shielding tape.

Although not explicitly illustrated in this specification, the functional layer FCL may additionally be configured to provide other functions by applying a resin that contains a filler with various functionalities. The resin may include a polymer resin. For example, the functional layer FCL may include acrylic resin, methacrylic resin, polyisoprene, vinyl resin, epoxy resin, urethane resin, cellulose resin, or parylene resin.

Moreover, the functional layer FCL may be formed by, but not limited to, coating the resin and then ultraviolet (UV) curing, thermal curing, or natural curing the coated resin.

For example, the functional layer FCL may include a cushion layer (not shown), a shielding layer (not shown), and a heat dissipation layer (not shown). The cushion layer (not shown) may be configured to protect the display panel DP from external impacts or interference transmitted toward the rear surface of the display panel DP. The shielding layer (not shown) may be configured to block electromagnetic waves generated by components of the display module DPM. The heat dissipation layer (not shown) may be configured to disperse heat emitted from the display panel DP.

For the convenience of description, the functional layer FCL is illustrated as a single layer in this specification. However, the present disclosure is not limited thereto, and the functional layer FCL may be provided in plurality.

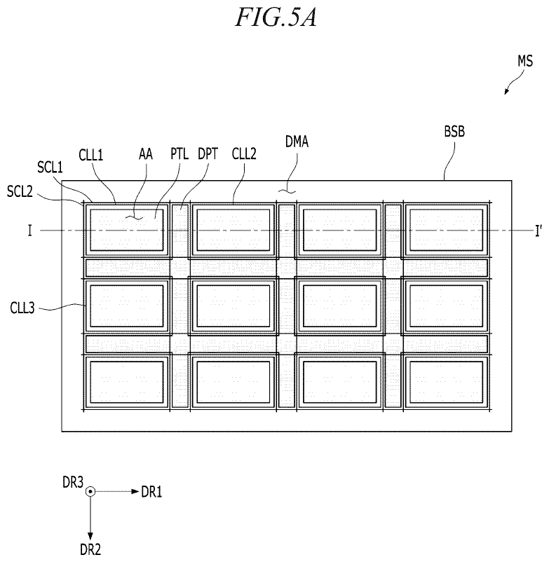

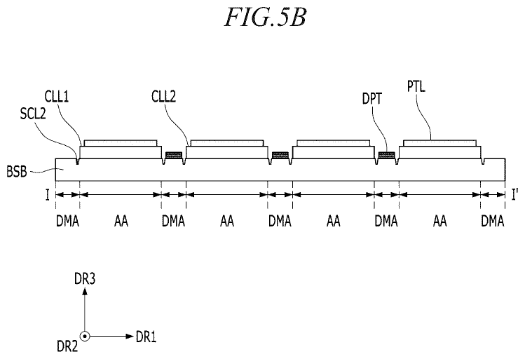

FIG. 5A is a plan view illustrating a mother substrate MS according to an embodiment of the present disclosure. FIG. 5B is a cross-sectional view taken along line I-I′ of FIG. 5A. As used herein, the ‘plan view” of the mother substrate is a view in a thickness direction (i.e., third direction DR3) of the mother substrate.

The mother substrate MS according to an embodiment of the present disclosure may include a base substrate BSB, a plurality of cells CLL1-CLL3, a plurality of protective layers PLT, and a dummy pattern DPT.

The base substrate BSB may have a plate shape extending in a first direction DR1 and a second direction DR2. For example, the base substrate BSB may have a rectangular plate shape. The base substrate BSB may serve as a base on which the plurality of cells CLL1-CLL3 are formed. In this specification, the base substrate BSB is exemplified as being formed of glass. Since glass has greater rigidity than plastic materials, it may allow the plurality of cells CLL1-CLL3 to be formed thereon without the need for an additional supporting substrate. Therefore, when the base substrate BSB is made of glass, the processes associated with attaching and detaching a supporting substrate may be omitted. However, the present disclosure is not limited thereto, and the base substrate BSB may alternatively be made of a flexible plastic material. For example, the base substrate BSB may be made of polyimide.

In an embodiment of the disclosure, a plurality of active areas AA and a dummy area DMA surrounding the plurality of active areas AA may be defined on the base substrate BSB. The plurality of active areas AA may be regions overlapping the plurality of cells CLL1-CLL3.

The plurality of cells CLL1-CLL3 may be disposed on the base substrate BSB. Each of the plurality of cells CLL1-CLL3 may correspond to a display panel DP as described in FIG. 4. That is, each of the plurality of cells CLL1-CLL3 may include a circuit layer, a light-emitting layer, and an encapsulation layer. In FIG. 5A, for the convenience of description, each of the plurality of cells CLL1-CLL3 is illustrated as a single layer, but the present disclosure is not limited thereto.

The circuit layer may be disposed on the base substrate BSB and may include a plurality of transistors (see FIG. 4). The light-emitting layer may be disposed on the circuit layer and may include a plurality of light-emitting diodes (see FIG. 4). The encapsulation layer may be disposed on the light-emitting layer.

In this specification, twelve cells are illustrated on the base substrate BSB, and three of these twelve cells will be described as examples. The plurality of cells CLL1-CLL3 may include a first cell CLL1, a second cell CLL2, and a third cell CLL3.

The first cell CLL1 may be the cell located furthest to the left along the first direction DR1 of the base substrate BSB. The second cell CLL2 may be a cell spaced from the first cell CLL1 in the first direction DR1. In this specification, the second cell CLL2 may be a cell spaced from and closest to the first cell CLL1 in the first direction DR1. The third cell CLL3 may be a cell spaced from the first cell CLL1 in the second direction DR2. In this specification, the third cell CLL3 may be a cell spaced from and closest to the first cell CLL1 in the second direction DR2. However, the present disclosure is not limited thereto.

Each of the plurality of cells CLL1-CLL3 may be disposed to overlap the plurality of active areas AA in a plan view. The plurality of active areas AA may correspond to regions where the light-emitting diodes LD and the encapsulation layer TFE are located (see FIG. 4). Each of the plurality of cells CLL1-CLL3 may be electrically connected to an outside via an external terminal (not shown) coupled to signal pads PD (see FIG. 3).

Each of the plurality of protective layers PTL may be disposed on the plurality of cells CLL1-CLL3 and may overlap the plurality of active areas AA in a plan view.

During the manufacturing process of the display panel DP, a cell-cutting process and a module process are sequentially performed. A component is needed to protect the plurality of cells CLL1-CLL3 from being damaged during the transition from the cell-cutting process to the module process. Each of the plurality of protective layers PTL may serve to protect the plurality of cells CLL1-CLL3 from damage.

Each of the plurality of protective layers PTL may include an organic material. The plurality of protective layers PTL may include at least one of an acrylic resin, an epoxy resin, and a silicon resin. However, the disclosure is not limited thereto. For example, the plurality of protective layers PTL may include two or more different types among acrylic resin, epoxy resin, and silicon resin.

The plurality of protective layers PTL may have a thickness ranging from 100 micrometers to 150 micrometers in the third direction DR3. Preferably, the plurality of protective layers PTL may have a thickness of 120 micrometers. However, the present disclosure is not limited thereto. If the thickness of the plurality of protective layers PTL is less than 100 micrometers, the layers may be too thin to sufficiently protect the plurality of cells CLL1-CLL3, increasing the risk of damage. If the thickness of the plurality of protective layers PTL exceeds 150 micrometers, an excessive amount of the organic material must be discharged from the inkjet printing device, rendering the process inefficient.

The dummy pattern DPT may overlap the dummy area DMA in a plan view and may be made of the same material as the plurality of protective layers PTL. Since the material of the dummy pattern DPT is substantially the same as that of the protective layers PTL described above, a redundant description is omitted.

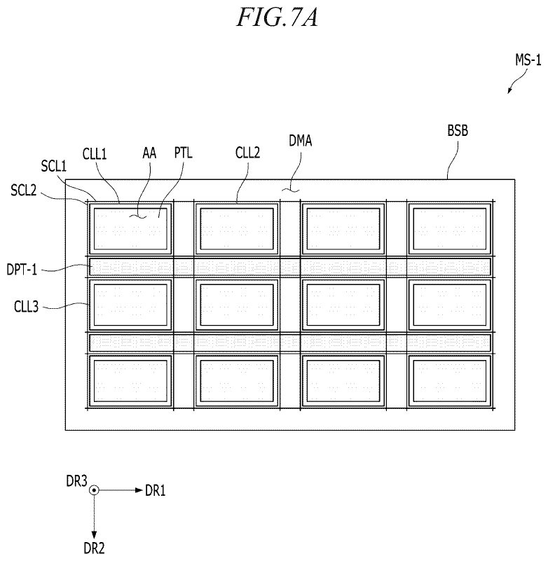

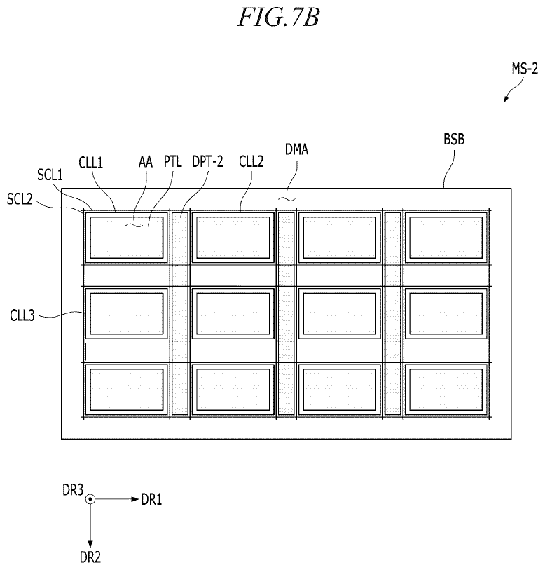

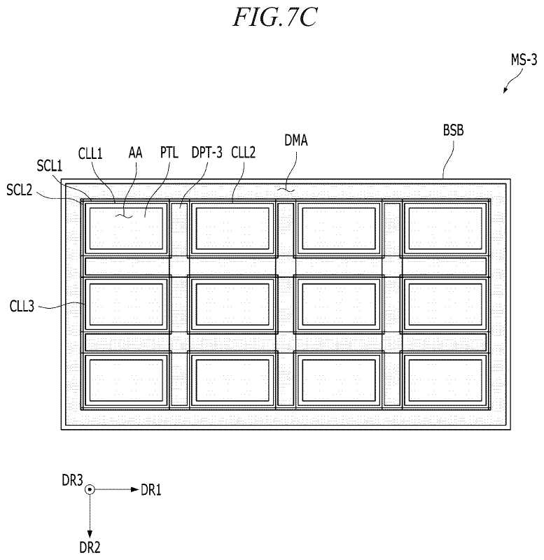

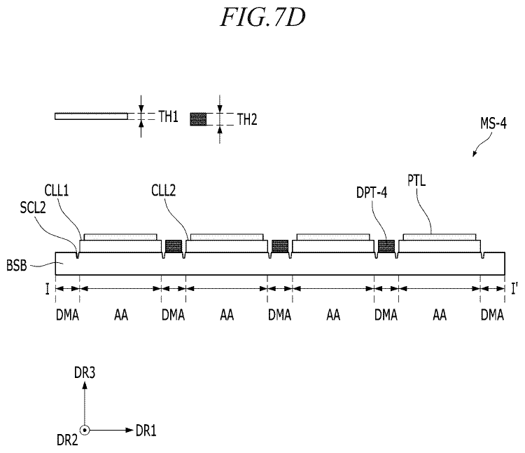

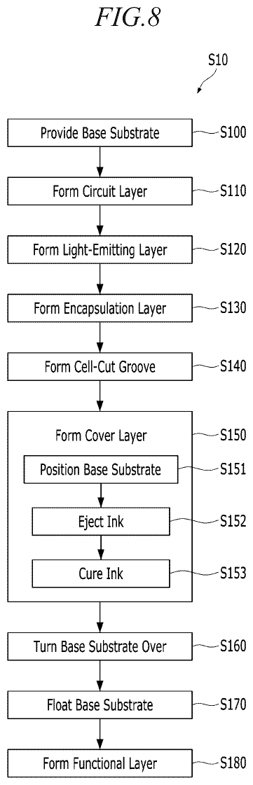

The dummy pattern DPT may have the same thickness as, or a different thickness from, the plurality of protective layers PTL. For example, the plurality of protective layers PTL may have a thickness of 120 micrometers, and the dummy pattern DPT may have a greater thickness of 130 micrometers. A detailed description of this will be provided later with reference to FIG. 7D.

In an embodiment of the present disclosure, a plurality of cell-cut grooves SCL1, SCL2 may be defined in the dummy area DMA. The plurality of cell-cut grooves SCL1, SCL2 may include a plurality of first cell-cut grooves SCL1 and a plurality of second cell-cut grooves SCL2. Each of the plurality of first cell-cut grooves SCL1 may extend along the first direction DR1. Each of the plurality of second cell-cut grooves SCL2 may extend along a second direction DR2 intersecting the first direction DR1.

The plurality of cell-cut grooves SCL1, SCL2 may be scribing lines on which physical force is applied by a wheel cutter (not shown). When the base substrate BSB is cut along the plurality of cell-cut grooves SCL1, SCL2 by the wheel cutter (not shown), a plurality of separated cells CLL1-CLL3 corresponding to the display panels DP may be obtained.

In an embodiment of the present disclosure, a portion of the dummy pattern DPT may be located between two adjacent second cell-cut grooves SCL2 of the plurality of second cell-cut grooves SCL2.

In an embodiment of the disclosure, another portion of the dummy pattern DPT may be located between two adjacent first cell-cut grooves SCL1 of the plurality of first cell-cut grooves SCL1.

In an embodiment of the disclosure, yet another portion of the dummy pattern DPT may be located between the outermost first cell-cut groove SCL1 among the plurality of first cell-cut grooves SCL1 and one side of the base substrate BSB adjacent to the outermost first cell-cut groove SCL1. (See FIG. 7C)

In an embodiment of the disclosure, still another portion of the dummy pattern DPT may be located between the outermost second cell-cut groove SCL2 among the plurality of second cell-cut grooves SCL2 and another side of the base substrate BSB adjacent to the outermost second cell-cut groove SCL2. (See FIG. 7C)

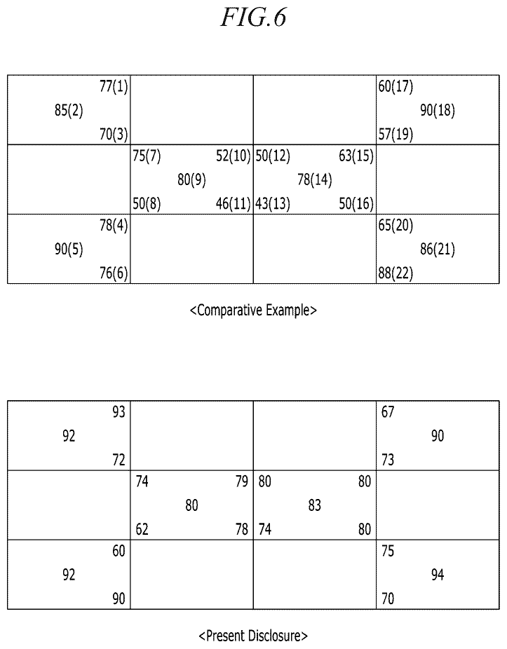

In a comparative example shown in FIG. 6, the extent to which the base substrate BSB floats above the stage is illustrated for a case where the dummy pattern is not applied. In contrast, the embodiment of the present disclosure in FIG. 6 illustrates the extent of floatation of the base substrate BSB above the stage when the dummy pattern is applied.

Before describing FIG. 6 in detail, the terms minimum float height and float deviation will be first described. The minimum float height refers to the minimum distance by which the base substrate BSB is spaced from the stage. The float deviation refers to the difference between the minimum and maximum float heights.

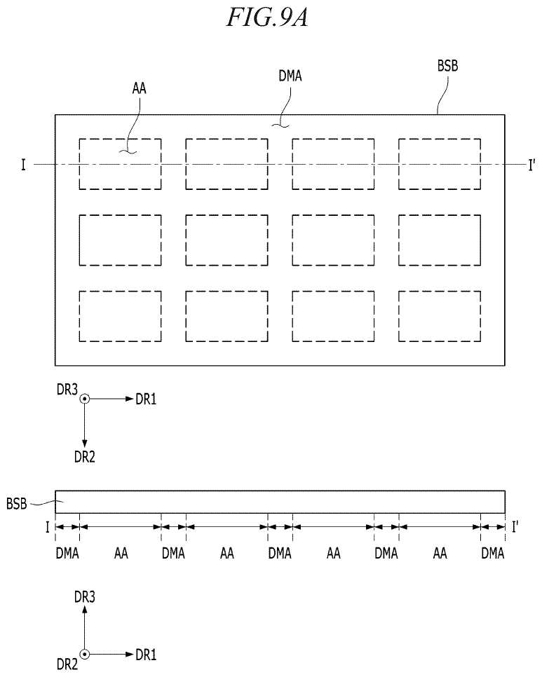

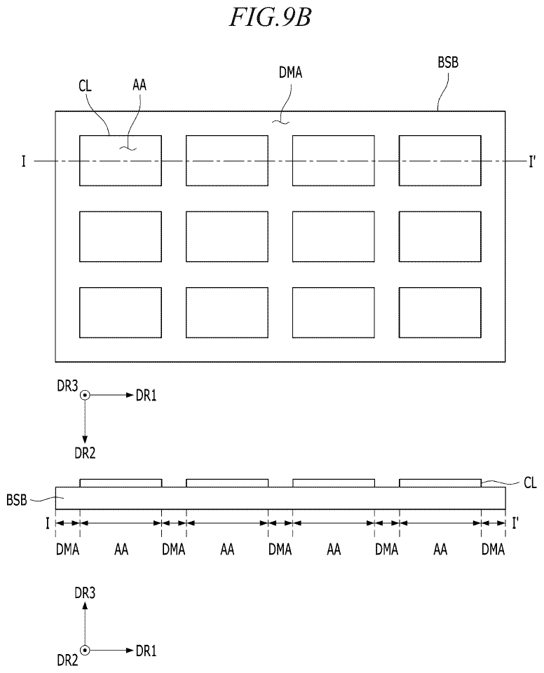

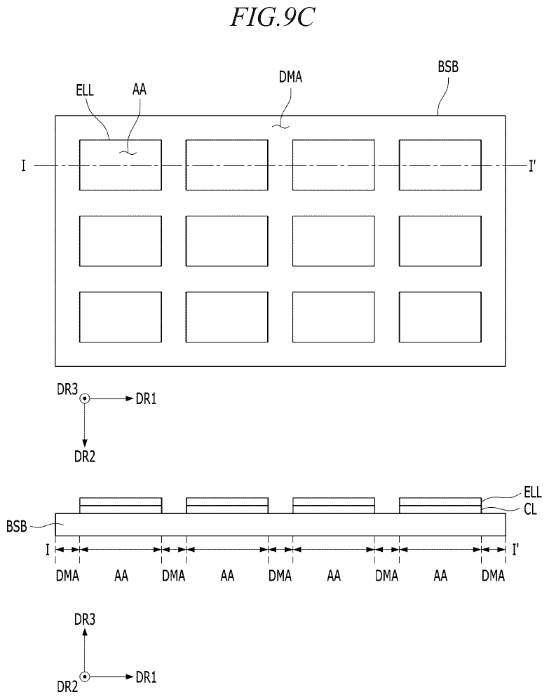

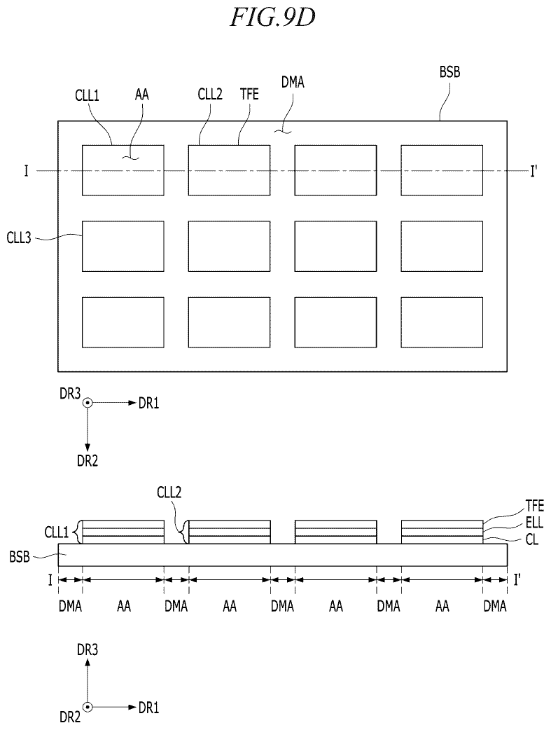

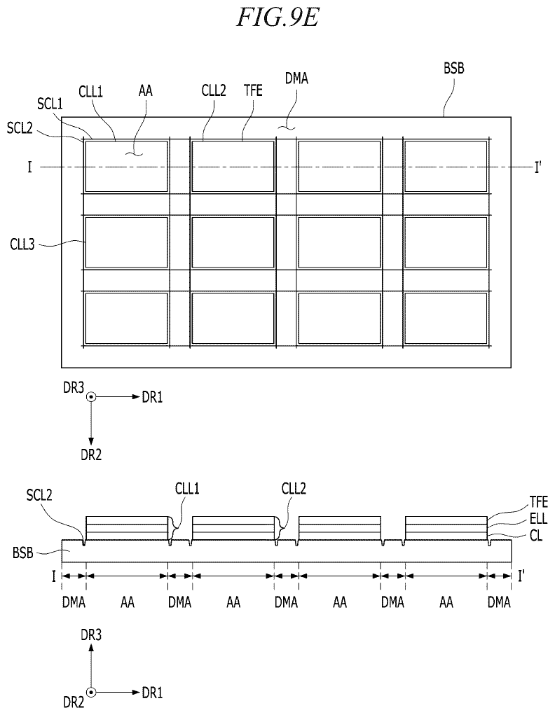

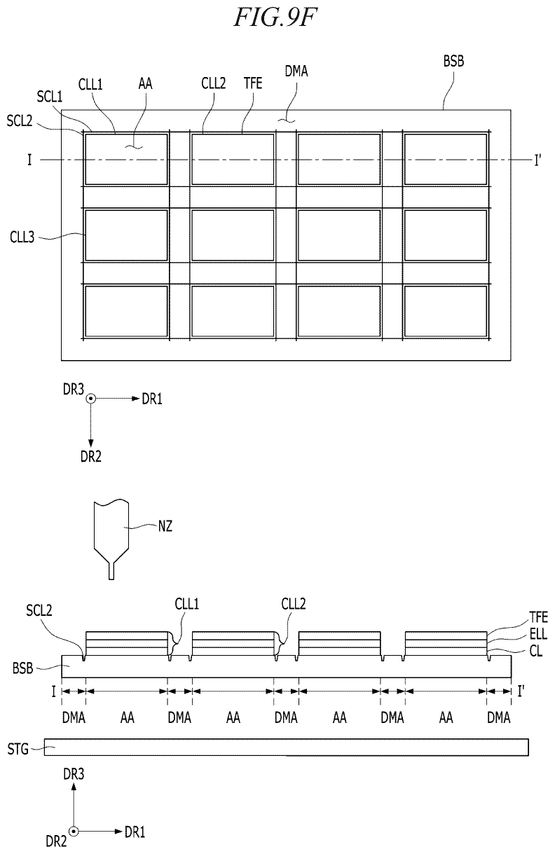

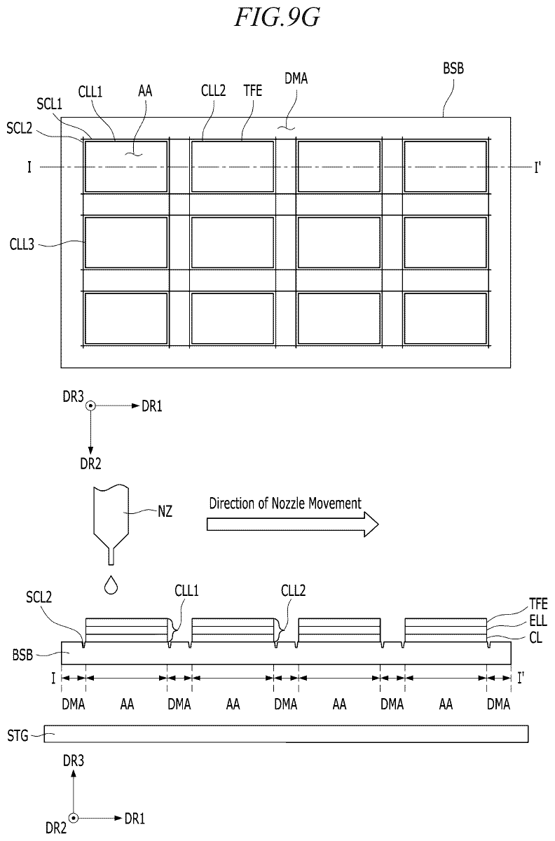

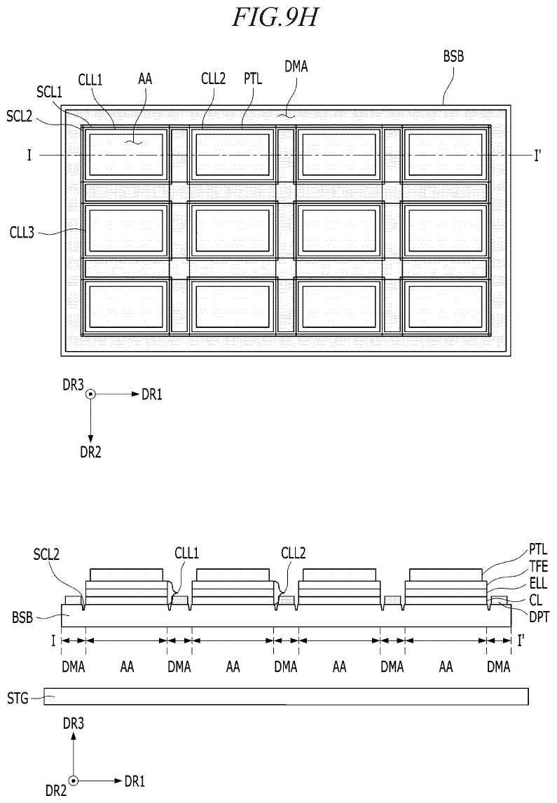

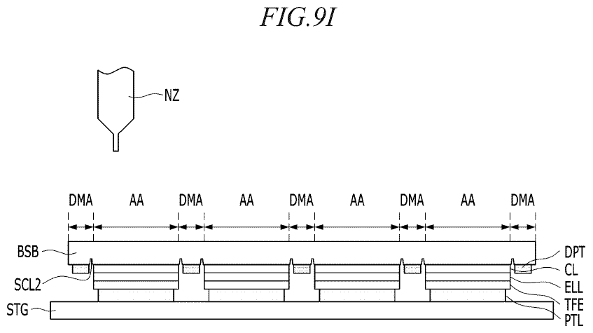

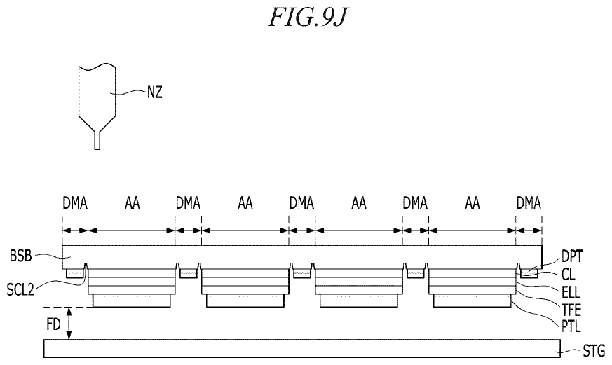

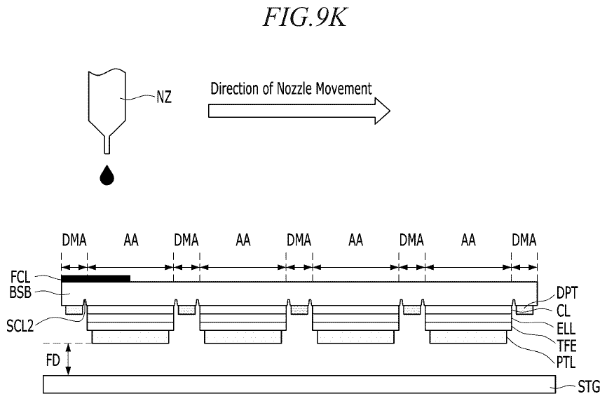

As previously described with reference to FIGS. 5A and 5B, a plurality of cells CLL1-CLL3, a plurality of protective layers PTL, and a dummy pattern DPT are formed on the front surface of the base substrate BSB. As will be described later with reference to FIG. 9L, a functional layer is formed on the rear surface of the base substrate BSB. In an embodiment of the present disclosure, the functional layer may be formed by directly coating resin onto the rear surface of the base substrate BSB. To summarize, in the present specification, the plurality of cells CLL1-CLL3, the plurality of protective layers PTL, the dummy pattern DPT, and the functional layer may be formed by an inkjet printing device. The inkjet printing device may include a stage and a nozzle unit located on the stage.

Since the plurality of cells CLL1-CLL3, the plurality of protective layers PTL, and the dummy pattern DPT are formed on the front surface of the base substrate BSB, the rear surface of the base substrate BSB is placed on the stage of the inkjet printing device.

On the other hand, when forming the functional layer on the rear surface of the base substrate BSB, the rear surface of the base substrate BSB and the nozzle unit may be arranged to face each other. In this arrangement, the front surface of the base substrate BSB faces the stage. Although the front surface of the base substrate BSB includes the plurality of protective layers PTL and the dummy pattern DPT, these layers are relatively thin and thus vulnerable to external stress. Therefore, the base substrate BSB needs to be floated a certain distance above the stage to prevent damage to the front surface of the base substrate BSB. While securing the minimum float height, an appropriate float distance needs to be provided so that the base substrate BSB is not spaced too far from the stage. If the base substrate BSB is excessively spaced from the stage, the components of the base substrate BSB may contact the nozzle unit on the stage, hindering a smooth inkjet printing process.

When forming the functional layer on the rear surface of the base substrate BSB, the base substrate BSB may be air-floated in a non-contact state with the stage.

If no components are formed in the dummy area DMA, the base substrate BSB may warp or bend due to a thickness difference between the plurality of active areas AA and the dummy area DMA. Furthermore, due to the material properties (e.g., shrinkage) of the plurality of protective layers PTL positioned on the active areas AA, the base substrate BSB may also warp or bend.

In summary, by ensuring a minimum float height of at least 40 micrometers and reducing the float deviation, it is possible to prevent the base substrate BSB from warping or twisting during the manufacturing process of the display panel. The results of FIG. 6 are summarized in Table 1 below.

TABLE 1

| Measurement | Comparative Example | Present Disclosure |
|---|---|---|
| Point | (unit: micrometer) | (unit: micrometer) |
| 1 | 77 | 93 |
| 2 | 85 | 95 |
| 3 | 70 | 72 |
| 4 | 78 | 60 |
| 5 | 90 | 92 |
| 6 | 76 | 90 |
| 7 | 75 | 74 |
| 8 | 50 | 62 |
| 9 | 80 | 80 |
| 10 | 52 | 79 |
| 11 | 46 | 78 |
| 12 | 50 | 80 |
| 13 | 43 | 74 |
| 14 | 78 | 83 |
| 15 | 63 | 80 |
| 16 | 50 | 80 |
| 17 | 60 | 67 |
| 18 | 90 | 90 |
| 19 | 57 | 73 |
| 20 | 65 | 75 |
| 21 | 86 | 94 |
| 22 | 88 | 70 |

In this context, the measurement points may correspond to specific regions within some of the plurality of cells CLL1-CLL12. In describing FIG. 6, the plurality of cells are based on a total of twelve, and the cells are arranged in cell rows and cell columns-specifically, three cell rows and four cell columns.

The first cell row includes first to fourth cells, with the first cell positioned farthest to the left along the first direction DR1, and the second to fourth cells sequentially arranged along a second direction DR2 intersecting the first direction. The second cell row includes fifth to eighth cells, with the fifth cell positioned farthest to the left along the first direction DR1, and the sixth to eighth cells sequentially arranged along the second direction DR2. The third cell row includes ninth to twelfth cells, with the ninth cell positioned farthest to the left along the first direction DR1, and the tenth to twelfth cells sequentially arranged along the second direction DR2.

Measurement points 1, 2, and 3 show the extent to which certain points inside the first cell are spaced from the stage. Measurement points 4, 5, and 6 show the extent to which certain points inside the ninth cell are spaced from the stage. Measurement points 7, 8, 9, 10, and 11 show the extent to which certain points inside the sixth cell are spaced from the stage. Measurement points 12, 13, 14, 15, and 16 show the extent to which certain points inside the seventh cell are spaced from the stage. Measurement points 17, 18, and 19 show the extent to which certain points inside the fourth cell are spaced from the stage. Measurement points 20, 21, and 22 show the extent to which certain points inside the twelfth cell are spaced from the stage.

In the comparative example of FIG. 6, the smallest spacing from the stage is at measurement point 13, which is 43 micrometers. The greatest spacing is at measurement points 5 and 18, both showing 90 micrometers. That is, the float deviation—i.e., the difference between minimum float height and maximum float height—is 47 micrometers.

In the embodiment of the present disclosure of FIG. 6, the smallest spacing is at measurement point 4, which is 60 micrometers. The greatest spacing is at measurement point 2, which is 95 micrometers. That is, the float deviation is 35 micrometers.

Analyzing the results of FIG. 6, compared to the comparative example, the embodiment of the present invention increased the minimum float height by 17 micrometers and reduced the float variation by 12 micrometers.

Therefore, by adding dummy patterns DPT in the dummy area DMA, the present disclosure can effectively resolve the above-described problems. Since the dummy pattern DPT is formed using the same material as the plurality of protective layers PTL and is applied through an inkjet printing device, no additional equipment is needed. The dummy pattern DPT of the present disclosure prevents the base substrate BSB from warping during the display panel manufacturing process, thereby improving process efficiency.

FIG. 7A is a plan view of a mother substrate MS-1 according to another embodiment of the present disclosure. FIG. 7A differs from FIG. 5A only in the placement of a dummy pattern DPT-1. In FIG. 7A, unlike in FIG. 5A, the dummy pattern DPT-1 is positioned between first cell-cut grooves SCL1, excluding the outermost first cell-cut groove SCL1 among the plurality of first cell-cut grooves SCL1. Additionally, the dummy pattern DPT-1 is not positioned between second cell-cut grooves SCL2. Compared to FIG. 5A, since the dummy pattern DPT-1 is not placed between the plurality of second cell-cut grooves SCL2, the amount of ink discharged from the inkjet printing device can be reduced. Accordingly, the amount of material used in the manufacturing process can be conserved.

FIG. 7B is a plan view of a mother substrate MS-2 according to yet another embodiment of the present disclosure. FIG. 7B differs from FIG. 5A only in the placement of a dummy pattern DPT-2. Unlike in FIG. 5A, in FIG. 7B, the dummy pattern DPT-2 is positioned between the second cell-cut grooves SCL2, excluding the outermost second cell-cut groove SCL2 among the plurality of second cell-cut grooves SCL2. Additionally, the dummy pattern DPT-2 is not positioned between the first cell-cut grooves SCL1. Compared to FIG. 5A, since the dummy pattern DPT-2 is not placed between the plurality of first cell-cut grooves SCL1, the amount of ink discharged from the inkjet printing device can be reduced. Accordingly, the amount of material used in the manufacturing process can be conserved.

FIG. 7C is a plan view of a mother substrate MS-3 according to still another embodiment of the present disclosure. Unlike FIGS. 7A and 7B, in FIG. 7C, the dummy pattern DPT-3 is further placed between the outermost first cell-cut groove SCL1 among the plurality of first cell-cut grooves SCL1 and one side (e.g., upper side extending along the first direction DR1) of the base substrate BSB adjacent to the outermost first cell-cut groove SCL1. In addition, the dummy pattern DPT-3 is further placed between the outermost second cell-cut groove SCL2 among the plurality of second cell-cut grooves SCL2 and another side (e.g., left side extending along the second direction DR2) of the base substrate BSB adjacent to the outermost second cell-cut groove SCL2. This configuration can effectively prevent the base substrate BSB from being warped or bent during subsequent formation of the functional layer, by reducing the thickness variation between the plurality of active areas AA and the dummy area DMA.

FIG. 7D is a cross-sectional view illustrating a mother substrate MS-4 according to another embodiment of the present disclosure. Unlike FIG. 5B, FIG. 7D illustrates that the thicknesses of the plurality of protective layers PTL and a dummy pattern DPT-4 are different. The plurality of protective layers PTL may have a first thickness TH1 in the third direction DR3, and the dummy pattern DPT may have a second thickness TH2 in the third direction DR3. The plurality of protective layers PTL overlap the plurality of active areas AA in a plan view and thus may be thicker than a dummy area DMA. Therefore, by forming the dummy pattern DPT to be thicker than the plurality of protective layers PTL, the thickness variation between the plurality of protective layers PTL and the dummy pattern DPT-4 can be reduced. This can effectively prevent warping or bending of the base substrate BSB due to thickness variation during the formation of the functional layer. For example, if the plurality of protective layers PTL are 120 micrometers thick, the dummy pattern DPT-4 may be thicker, such as 130 micrometers. However, the disclosure is not limited thereto, and the thicknesses of the plurality of protective layers PTL and the dummy pattern DPT-4 may be varied as needed.

FIG. 8 is a flow diagram schematically illustrating a method of manufacturing a display panel according to an embodiment of the present disclosure. FIGS. 9A through 9K sequentially illustrate a method of manufacturing a display panel according to an embodiment of the present disclosure.

The method of manufacturing a display panel (S10) may include providing a base substrate (S100), forming a circuit layer (S110), forming a light-emitting layer (S120), forming an encapsulation layer (S130), forming a cell-cut groove (S140), forming a cover layer (S150), turning the base substrate over (S160), floating the base substrate (S170), and forming a functional layer (S180).

The step of forming a cover layer (S150) may include positioning the base substrate (S151), ejecting ink (S152), and curing the ink (S153). However, the order of the process steps is not limited thereto.

Referring to FIGS. 8 and 9A, the step of providing a base substrate (S100) may be performed. The step of providing a base substrate (S100) may involve providing a base substrate BSB. The materials of the base substrate BSB and the regions defined thereon are substantially identical to the description provided above with reference to FIGS. 5A and 5B and thus will not be repeated here.

Referring to FIGS. 8 and 9B, after the step of providing a base substrate (S100), the step of forming a circuit layer (S110) may be performed. In the step of forming a circuit layer (S110), a circuit layer CL may be formed on the base substrate BSB. The circuit layer CL may be positioned to overlap a plurality of active areas AA in a plan view. In FIG. 9B, the circuit layer CL is illustrated as a single layer for convenience. However, it should be understood that the circuit layer CL may include individual components, such as the plurality of transistors described with reference to FIG. 4.

Referring to FIGS. 8 and 9C, after the step of forming a circuit layer (S110), the step of forming a light-emitting layer (S120) may be performed. In the step of forming a light-emitting layer (S120), a light-emitting layer ELL may be formed on the circuit layer CL. In FIG. 9C, the light-emitting layer ELL is illustrated as a single layer for convenience. However, it should be understood that the light-emitting layer ELL may include individual components such as the light-emitting diodes described in FIG. 4.

Referring to FIGS. 8 and 9D, after the step of forming a light-emitting layer (S120), the step of forming an encapsulation layer (S130) may be performed. In the step of forming an encapsulation layer (S130), an encapsulation layer TFE may be formed on the light-emitting layer ELL. In FIG. 9D, the encapsulation layer TFE is illustrated as a single layer for convenience of illustration. However, it is to be understood as including the individual components described earlier with reference to FIG. 4. Hereinafter, the stacked structure sequentially including the circuit layer CL, the light-emitting layer ELL, and the encapsulation layer TFE may collectively be referred to as a plurality of cells CLL1-CLL3.

Referring to FIGS. 8 and 9E, after the step of forming an encapsulation layer (S130), the step of forming a cell-cut groove (S140) may be performed, in which a plurality of cell-cut grooves SCL1, SCL2 may be provided. The plurality of cell-cut grooves SCL1, SCL2 may be formed on one surface of the base substrate BSB. Specifically, the plurality of cell-cut grooves SCL1, SCL2 may be formed by irradiating a laser (not shown) onto the one surface of the base substrate BSB and may have a groove shape in which a portion of the base substrate BSB is recessed. The plurality of cell-cut grooves SCL1, SCL2 may be formed to surround the peripheries of the plurality of cells CLL1-CLL3. The shape of the plurality of cell-cut grooves SCL1, SCL2 is substantially the same as that described earlier with reference to FIGS. 5A and 5B, and thus a repeated description will be omitted.

Referring to FIGS. 8 and 9F, after the step of forming a cell-cut groove (S140), the step of forming a cover layer (S150) may be performed. Specifically, in the step of forming a cover layer (S150), the step of positioning the base substrate (S151) may be performed. In the step of positioning the base substrate (S151), the encapsulation layer TFE of the base substrate BSB may be positioned to face a nozzle unit NZ. In this specification, although the base substrate BSB and the stage STG are illustrated as being spaced apart for the purpose of illustrating the defined regions of the base substrate BSB, it is to be understood that in actual implementation, the base substrate BSB is disposed on the stage STG without being spaced apart.

Although not illustrated in this specification, after the step of forming a cover layer (S150), the method may further include forming an organic layer (not shown), attaching an acid-resistant film (not shown), spraying an etching solution (not shown), peeling off the acid-resistant film (not shown), and peeling off the organic layer (not shown).

In the step of forming an organic layer (not shown), an organic layer configured to shield the outer regions and openings (not shown) of the plurality of cells CLL1-CLL3 may be formed. The material of the organic layer may be the same as the material forming the plurality of protective layers PTL.

In the step of attaching an acid-resistant film (not shown), an acid-resistant film (not shown) may be attached to the base substrate. The acid-resistant film may include an acid-resistant material that does not react with strong acids or hydrofluoric acid. The acid-resistant film (not shown) may include a base layer (not shown) and an adhesive layer (not shown).

The base layer may include a plastic film. For example, the base layer may be made of, but not limited to, polyethersulfone (PES), polyacrylate (PAR), polyetherimide (PEI), polyethylene naphthalate (PEN), polyethylene terephthalate (PET), polyphenylene sulfide (PPS), polyarylate, polyimide (PI), polycarbonate (PC), or poly aryleneether sulfone.

The adhesive layer may be formed by coating a liquid adhesive on the underside the base layer. For example, the adhesive layer may be formed using a roll coater (not shown), a knife coater (not shown), or a micro gravure coater (not shown).

The adhesive layer may be an organic adhesive layer such as a pressure-sensitive adhesive film (PSA), an optically clear adhesive film (OCA), or an optically clear resin (OCR). The organic adhesive layer may include adhesive materials such as polyurethane, polyacrylate, polyester, polyepoxy, or polyvinyl acetate.

In the step of spraying an etching solution (not shown), an etching solution may be sprayed onto the base substrate. The etching solution used in the step of spraying an etching solution (not shown) may include hydrofluoric acid (HF) or other fluoride-based substances.

The step of spraying an etching solution (not shown) may be performed using, for example, a dipping method (not shown), a spraying method (not shown), or a top-down etching method (not shown).

In the dipping method, the base substrate BSB may be vertically dipped in a bath (not shown) for etching. In the spraying method, the etching solution may be sprayed onto both surfaces of a vertically positioned base substrate BSB via a spray nozzle. In the top-down etching method, the etching solution may be poured from above onto the vertically positioned base substrate BSB for etching.

As the etching solution flows down from the top of the base substrate BSB, the thickness of the base substrate BSB may be reduced, allowing the base substrate BSB to be cut. For example, the thickness of the base substrate BSB may be reduced, but not limited to, from 500 micrometers to 200 micrometers.

In the step of peeling off the acid-resistant film (not shown), the acid-resistant film may be removed from the base substrate using a peeling pin (not shown). The acid-resistant film may be laminated to prevent the etching solution from penetrating the plurality of cells and may be removed after the step of spraying an etching solution.

In the step of peeling off the organic layer (not shown), the organic layer may be removed from the base substrate. The organic layer may serve to prevent the etching solution from penetrating the plurality of cells and may be removed after the step of spraying an etching solution.

Referring to FIGS. 8 and 9G, after the step of positioning the base substrate (S151), the step of ejecting ink (S152) may be performed. In the step of ejecting ink (S152), a nozzle unit NZ of the inkjet printing device may eject ink onto the base substrate BSB. The ink may include an organic material. The description of the organic material is substantially the same as that described above with reference to FIGS. 5A and 5B and thus will not be redundantly provided.

Referring to FIGS. 8 and 9H, after the step of ejecting ink (S152), the step of curing the ink (S153) may be performed. In the step of curing the ink (S153), the ink may be cured using ultraviolet curing, thermal curing, or natural curing. In the present disclosure, the cover layer may refer to the plurality of protective layers PTL and the dummy pattern DPT.

Referring to FIGS. 8 and 9I, after the step of curing the ink (S153), the step of turning the base substrate over (S160) may be performed. In the step of turning the base substrate over (S160), the rear surface of the base substrate BSB may be positioned to face the nozzle unit NZ, and the encapsulation layer TFE may be positioned to face the stage STG.

Referring to FIGS. 8 and 9J, after the step of turning the base substrate over (S160), the step of floating the base substrate (S170) may be performed. In the step of floating the base substrate (S170), the base substrate BSB may be spaced apart from the stage STG by a floating distance FD.

Although not shown explicitly in the specification, a plurality of holes may be formed in the stage STG. The plurality of holes may be configured to provide compressed air (positive pressure) or vacuum suction (negative pressure) in a direction toward the nozzle unit NZ from the stage STG. Accordingly, the base substrate BSB may be floated in a non-contact state with the stage STG while maintaining a constant floating distance FD.

Referring to FIGS. 8 and 9K, after the step of floating the base substrate (S170), the step of forming a functional layer (S180) may be performed. In the step of forming a functional layer (S180), a material having a black color may be coated on the rear surface of the base substrate BSB. The material being coated may include carbon black, graphite, and carbon nanotubes. The configuration and characteristics of the functional layer FCL are substantially the same as those previously described with reference to FIG. 4 and thus will not be redundantly described herein.

Although not explicitly illustrated in the specification, after the step of forming a functional layer (S180), the method may further include obtaining cells (not shown) and connecting a driving unit (not shown).

In the step of obtaining cells, a cutting process may be performed along the plurality of cell-cut grooves using a wheel cutter, thereby obtaining a plurality of separated cells corresponding to the display panel.

In the step of connecting a driving unit, the separated plurality of cells CLL1-CLL3 and a driving unit may be connected. For example, the step of connecting a driving unit may include mounting a driving IC, attaching a sensor layer or a window, and mounting signal pads PD of the display panel DP.

While certain embodiments of the present disclosure have been described herein, anyone ordinarily skilled in the art to which the present disclosure pertains shall appreciate that there may be a variety of modifications and permutations of the present disclosure without departing from the technical ideas and scopes of the present disclosure that are defined in the appended claims. Moreover, it shall be appreciated that the disclosed embodiments are not intended to restrict the present disclosure thereto and that every technical idea within the appended claims and their equivalents is interpreted to be included in the scope of the present disclosure.

What is claimed is:

1. A mother substrate comprising:
a base substrate in which a plurality of active regions and a dummy region surrounding the plurality of active regions are defined;
a plurality of cells positioned on the base substrate, overlapping the plurality of active regions, respectively, and comprising a plurality of light-emitting diodes;
a plurality of protective layers disposed on the plurality of cells, respectively, and overlapping the plurality of active regions, respectively; and
a dummy pattern overlapping the dummy region and formed of a same material as the plurality of protective layers.

2. The mother substrate of claim 1, wherein each of the plurality of cells comprises:
a circuit layer comprising a plurality of transistors and disposed on the base substrate;
a light-emitting layer disposed on the circuit layer and including at least some of the plurality of light-emitting diodes; and
an encapsulation layer disposed on the light-emitting layer.

3. The mother substrate of claim 2, wherein each of the plurality of protective layers comprises at least one of an acrylic resin, an epoxy resin, and a silicon resin.

4. The mother substrate of claim 2, wherein a plurality of cell-cut grooves are defined in the dummy region,
wherein the plurality of cell-cut grooves comprise:
a plurality of first cell-cut grooves, each extending along a first direction; and
a plurality of second cell-cut grooves, each extending along a second direction intersecting the first direction, and
wherein a portion of the dummy pattern is disposed between two adjacent second cell-cut grooves among the plurality of second cell-cut grooves.

5. The mother substrate of claim 4, wherein another portion of the dummy pattern is disposed between two adjacent first cell-cut grooves among the plurality of first cell-cut grooves.

6. The mother substrate of claim 4, wherein another portion of the dummy pattern is disposed between an outermost first cell-cut groove of the plurality of first cell-cut grooves and one side of the base substrate adjacent to the outermost first cell-cut groove.

7. The mother substrate of claim 4, wherein another portion of the dummy pattern is disposed between an outermost second cell-cut groove of the plurality of second cell-cut grooves and another side of the base substrate adjacent to the outermost second cell-cut groove.

8. The mother substrate of claim 2, further comprising a functional layer located under the base substrate.

9. The mother substrate of claim 8, wherein the functional layer comprises at least one of carbon black, graphite, and carbon nanotubes.

10. The mother substrate of claim 2, wherein a thickness of each of the plurality of protective layers is greater than or equal to 100 micrometers and smaller than or equal to 150 micrometers.

11. The mother substrate of claim 2, wherein a thickness of each of the plurality of protective layers is smaller than a thickness of the dummy pattern.

12. A method of manufacturing a display panel, comprising:
providing a base substrate in which a plurality of active regions and a dummy region surrounding the plurality of active regions are defined;
forming a circuit layer comprising a plurality of transistors overlapping the plurality of active regions on the base substrate;
forming a light-emitting layer comprising a plurality of light-emitting diodes on the circuit layer;
forming an encapsulation layer on the light-emitting layer; and
forming a cover layer by coating a material comprising an organic material to form a plurality of protective layers overlapping the plurality of active regions and a dummy pattern overlapping the dummy region.

13. The method of claim 12, further comprising forming a cell-cut groove,
wherein, in the forming of the cell-cut groove, a plurality of cell-cut grooves are defined in the dummy region,
wherein the plurality of cell-cut grooves comprise:
a plurality of first cell-cut grooves, each extending along a first direction; and
a plurality of second cell-cut grooves, each extending along a second direction intersecting the first direction, and
wherein a portion of the dummy pattern is disposed between two adjacent second cell-cut grooves of the plurality of second cell-cut grooves.

14. The method of claim 13, wherein another portion of the dummy pattern is disposed between two adjacent first cell-cut grooves of the plurality of first cell-cut grooves.

15. The method of claim 13, wherein another portion of the dummy pattern is disposed between an outermost first cell-cut groove of the plurality of first cell cut grooves and one side of the base substrate adjacent to the outermost first cell-cut groove.

16. The method of claim 12, wherein the forming of the cover layer is performed using an inkjet printing device comprising a stage and a nozzle unit disposed on the stage, and
wherein the forming of the cover layer comprises:
positioning the base substrate on the stage such that the encapsulation layer faces the nozzle unit;
ejecting ink, in which the organic material is ejected through the nozzle unit onto the plurality of active regions and the dummy region; and
curing the ink, in which the ejected organic material is cured.

17. The method of claim 12, wherein the organic material comprises at least one of an acrylic resin, an epoxy resin, and a silicon resin.

18. The method of claim 16, further comprising, after the forming of the cover layer:
turning the base substrate over such that a rear surface of the base substrate faces the nozzle unit;
floating the base substrate by supplying air from the stage toward the base substrate such that the base substrate is spaced apart from the stage; and
forming a functional layer by coating a material comprising black color to the rear surface of the base substrate.

19. The method of claim 16, wherein, after the ejecting of the ink, a thickness of each of the plurality of protective layers is smaller than a thickness of the dummy pattern.

20. The method of claim 18, wherein, after the forming of the functional layer, the functional layer comprises at least one of carbon black, graphite, and carbon nanotubes.
